(19) United States
(12) Patent Application Publication
(10) Pub. No.: US 2016/0322783 A1
(43) Pub. Date: Nov. 3, 2016

(54) INTEGRATED CIRCUIT INCORPORATING A COMPACT ARRANGEMENT OF COMPONENTS

(71) Applicant: Avago Technologies General IP (Singapore) Pte. Ltd, Singapore (SG)

(72) Inventors: Dezhao Bai, Sunnyvale, CA (US); Faouzi Chaahoub, San Jose, CA (US)

(21) Appl. No.: 14/700,299

(22) Filed: Apr. 30, 2015

(51) Int. Cl. H01S 5/042; H04B 10/40; H04B 10/60; H01S 5/183; H04B 10/50

(52) U.S. Cl. CPC H01S 5/042; H01S 5/183; H04B 10/50; H04B 10/60; H04B 10/40

(57) ABSTRACT

Compact component arrangements that can be incorporated into integrated circuits are disclosed. In each of these compact component arrangements, a pitch parameter of a first set of components is used to define a pitch parameter of a second set of components that is to be interconnected with the first set of components. In some example embodiments, the first set of components is a set of optical devices and the second set of components is a set of interface circuits (for example, transmitter circuits or receiver circuits). In other example embodiments, the first set of components is the set of interface circuits and the second set of components is a set of synchronizing circuits each of which can be used for example, to retime an electrical signal that is provided to a respective one of the set of interface circuits.

### FIELD OF THE INVENTION

The invention relates to integrated circuits, and more particularly, to integrated circuits containing multi-channel optical circuitry.

### BACKGROUND

The arrangement of components inside an integrated circuit (IC) is typically driven by a number of factors such as for example, the size and the shape of the various components, power consumption of the various components, signal integrity issues, and fabrication process limitations. In terms of size and shape, some components, such as for example, a resistor can be significantly smaller in size than an inductor. The inductor in turn, can be significantly smaller than a transistor array. Furthermore, in addition to being different in size, the shape of the inductor may require allocation of more surface area upon a substrate than that required for the resistor.

In terms of power consumption, a signal transmitter component may generate more heat than a signal receiver component, thereby necessitating more substrate real estate allocation and/or heat dissipating mechanisms. As for signal integrity issues, some components may emit an undesirable level of electro-magnetic interference (EMI) while others may fail to operate satisfactorily in the presence of such EMI. Appropriate care has to be taken when arranging the components with respect to each other so as to ensure that EMI does not cause circuit malfunction.

As for fabrication process limitations, some substrates allow for fabricating interconnecting tracks and structures that accommodate high frequency operation. While fabricating an IC using such a substrate may be desirable from an operational perspective, the cost of fabricating the IC can turn out to be undesirably high, especially when various components are not arranged optimally upon the substrate. In many cases, using a first arrangement of components in order to satisfy a first set of requirements can lead to a conflict in terms of satisfying a second set of requirements.

It is therefore desirable to provide solutions that address one or more IC packaging issues prevalent in traditional practice.

### BRIEF DESCRIPTION OF THE FIGURES

Many aspects of the invention can be better understood by referring to the following description in conjunction with the accompanying claims and figures. Like numerals indicate like structural elements and features in the various figures. For clarity, not every element may be labeled with numerals in every figure and not every similar element is shown in each figure or replicated in the various figures. The drawings are not necessarily drawn to scale, emphasis instead being placed upon illustrating the principles of the invention. The drawings should not be interpreted as limiting the scope of the invention to the example embodiments shown herein.

FIG. 1 shows a first exemplary embodiment of a compact component arrangement that can be incorporated into an integrated circuit in accordance with the disclosure.

FIG. 2 shows a second exemplary embodiment of a compact component arrangement that can be incorporated into an integrated circuit in accordance with the disclosure.

FIG. 3 shows a third exemplary embodiment of a compact component arrangement that can be incorporated into an integrated circuit in accordance with the disclosure.

FIG. 4 shows a fourth exemplary embodiment of a compact component arrangement that can be incorporated into an integrated circuit in accordance with the disclosure.

FIG. 5 shows a fifth exemplary embodiment of a compact component arrangement that can be incorporated into an integrated circuit in accordance with the disclosure.

FIG. 6 shows an exemplary floor plan matrix array in accordance with the disclosure.

FIG. 7 shows another exemplary floor plan matrix array in accordance with the disclosure.

### WRITTEN DESCRIPTION

Throughout this description, embodiments and variations are described for the purpose of illustrating uses and implementations of inventive concepts. The illustrative description should be understood as presenting examples of inventive concepts, rather than as limiting the scope of the concept as disclosed herein. It should be further understood that certain words and phrases are used herein solely for convenience and such words and phrases should be interpreted as referring to various objects and actions that are generally understood in various forms and equivalencies by persons of ordinary skill in the art. For instance, the phrase “metal track” as used herein not only refers to a metal track or trace on a substrate of an integrated circuit (IC) but can also refer to a metal track or trace on a printed circuit board. The phrase “metal track” can also refer to a metal wire such as for example a bonding wire that is used inside the IC. The words “connected” or “coupled” generally refer to two elements that have electrical connectivity with each other via a metal track or a wire for example. The words “arrangement,” “configuration,” and “layout” are generally synonymous with each other. The word “device” generally refers to a semiconductor chip such as for example, an integrated circuit (IC) or a hybrid microcircuit.

Words such as “horizontal,” “vertical,” “width,” and “height” are used herein solely for convenience and are to be interpreted accordingly when the overall orientation of an arrangement is different than that shown in one or more of the exemplary embodiments. Furthermore, the word “example” as used herein is intended to be non-exclusionary and non-limiting in nature. More particularly, the word “exemplary” as used herein indicates one among several examples, and it must be understood that no undue emphasis or preference is being directed to the particular example being described. It should also be understood that the inventive concepts disclosed herein are not necessarily limited to a “device,” and can be implemented in various other ways, such as for example, in the form of a circuit incorporating discrete components located on a printed circuit board (PCB).

In terms of a general overview, disclosed herein are a few examples of compact component arrangements that can be incorporated into integrated circuits. In each of these compact component arrangements a pitch parameter of a first set of components is used to define a pitch parameter of a second set of components that is to be interconnected with the first set of components. In some example embodiments, the first set of components is a set of optical devices and the second set of components is a set of interface circuits (for example, transmitter circuits or receiver circuits that are used to couple digital signals into or out of the optical devices). In other example embodiments, the first set of components is the set of interface circuits and the second set of components is a set of synchronizing circuits each of which can be used for example to retime an electrical signal that is provided to a respective one of the set of interface circuits.

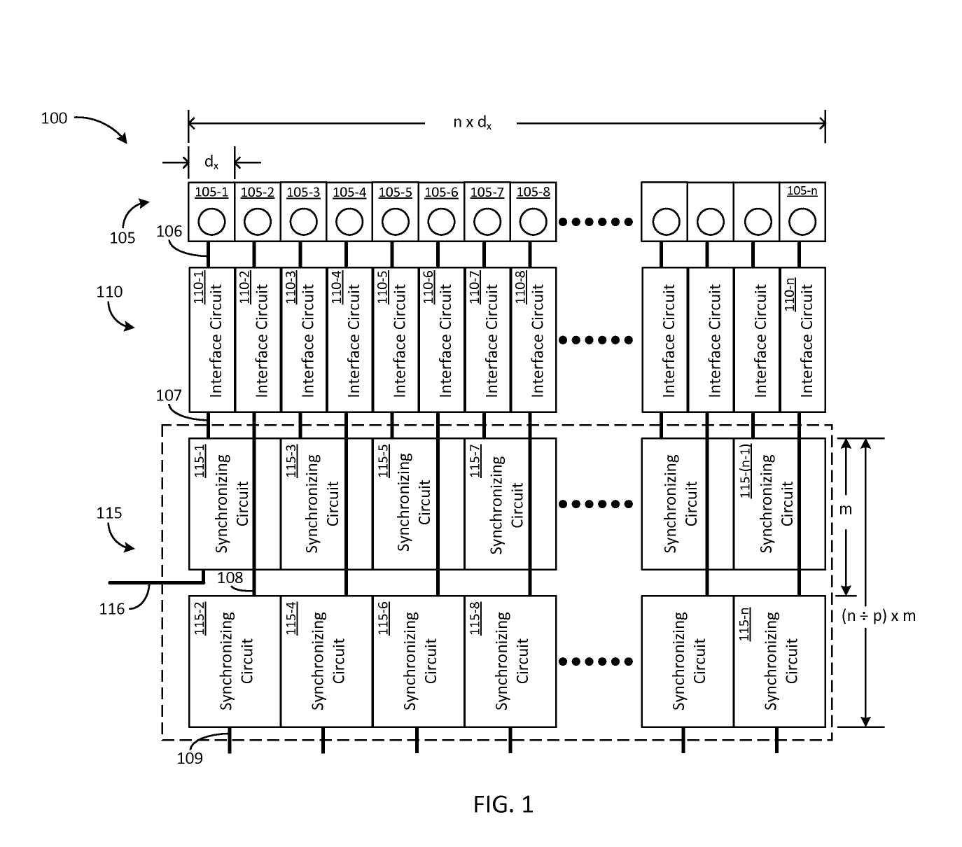

Attention is now drawn to FIG. 1, which shows a first exemplary embodiment of a compact component arrangement 100 that can be incorporated into an integrated circuit in accordance with the disclosure. The compact component arrangement 100 includes a first uniform linear array configuration 105 of “n” optical devices 105-1 through 105-n (n ≧2). In various implementations, “n” can be an even number that is an integer multiple of 2 such as for example, 2, 4, 6, or 8. For example, when the integrated circuit operates with signal bits in the form of nibbles, “n” can be 4, and when in the form of bytes, “n” can be 8. However, in various other implementations, “n” can be an odd number that is an integer multiple of 3, such as for example, 3, 6, 9, or 12.

The optical devices 105-1 through 105-n can be any of a number of optical devices that are similar to one another or different from one another. For example, in a first example implementation, each of the optical devices 105-1 through 105-n can be an optical emitter, such as a light emitting diode (LED) or a vertical cavity surface emitting laser (VCSEL). In a second example implementation, each of the optical devices 105-1 through 105-n can be an optical receiver, such as for example, a photodiode, an optical sensor, or an optical transducer. In a third example implementation, the optical devices 105-1 through 105-n can be a combination of one or more optical emitters and one or more optical receivers.

The compact component arrangement 100 also includes a second uniform linear array configuration 110 of “n” interface circuits 110-1 through 110-n each of which is interconnected to a corresponding one of the “n” optical devices 105-1 through 105-n. The interconnection is carried out using metal tracks provided on a substrate, such as, for example, a metal track 106 that interconnects the interface circuit 110-1 with the optical device 105-1. The interface circuits 110-1 through 110-n can be any of a number of circuits or devices that are similar to one another or different from one another. For example, in a first example implementation, each of the interface circuits 110-1 through 110-n can be a transmitter circuit that provides digital or analog electrical signals to corresponding optical devices 105-1 through 105-n. The digital or analog electrical signals activate the optical devices 105-1 through 105-n in accordance with various applications, such as for example to modulate light emitted by the optical devices 105-1 through 105-n. In a second example implementation, each of the interface circuits 110-1 through 110-n can be a receiver circuit that receives digital or analog electrical signals from corresponding optical devices 105-1 through 105-n. In a third example implementation, the interface circuits 110-1 through 110-n can be a combination of one or more transceiver circuits. In a fourth example implementation, the interface circuits 110-1 through 110-n can be a combination of one or more transmitter circuits, one or more receiver circuits, and one or more transceiver circuits.

The compact component arrangement 100 further includes a matrix array configuration 115 of “n” synchronizing circuits 115-1 through 115-n each of which is interconnected to a corresponding one of the “n” interface circuits 110-1 through 110-n. The interconnection is carried out using metal tracks provided on a substrate, such as, for example, a metal track 107 that interconnects the synchronizing circuit 115-1 with the interface circuit 110-1 and a metal track 108 that interconnects the synchronizing circuit 115-2 with the interface circuit 110-2. Further details pertaining to the layout of metal tracks such as the metal track 107 and the metal track 108 are described below using other figures.

Each of the “n” synchronizing circuits 115-1 through 115-n receives an input signal in the form of an analog or digital signal via a respective metal track. For example, synchronizing circuit 115-1 receives an analog or digital signal via a metal track 116 and synchronizing circuit 115-2 receives an analog or digital signal via a metal track 109. One or both of the metal track 116 and the metal track 109 can be laid out so as to provide connectivity to externally-accessible pins of an integrated circuit and/or other circuitry contained inside the integrated circuit in which the compact component arrangement 100 is located.

The synchronizing circuits 115-1 through 115-n can be any of a number of circuits or devices that are used to provide synchronizing functionality upon the digital or analog signals. For example, in one implementation, a first analog or digital signal that is provided to the synchronizing circuit 115-1 (via the metal track 116) may be offset in phase and/or frequency with respect to a second analog or digital signal that is provided to synchronizing circuit 115-2 (via the metal track 109). Each of the synchronizing circuit 115-1 and the synchronizing circuit 115-2 synchronizes a respective one of the first and the second analog or digital signals, such that the two signals are phase aligned with respect to each other and/or have an improved wave shape. In another example implementation, some or all of the synchronizing circuits 115-1 through 115-n can be clock signal generators or clock recovery circuits.

Having described the various exemplary components of the compact component arrangement 100, the relative positional relationships between these various components and the advantages derived thereof, will now be described in more detail. In this context, it will be pertinent to point out that the phrase “pitch parameter” is used herein to describe a horizontal separation distance pertaining to any two neighboring devices or circuits of the compact component arrangement 100.

More particularly, with respect to the first uniform linear array configuration 105 of “n” optical devices 105-1 through 105-n, and using the optical device 105-1 as an example component, a first pitch parameter defines a horizontal distance “dₓ” between one side of the optical device 105-1 and a corresponding side of a neighboring optical device 105-2, wherein the two sides are oriented parallel to each other. The horizontal distance “dₓ” is replicated amongst each adjacent pair of optical devices 105-2 through 105-n. Accordingly, the overall linear width of the first uniform linear array configuration 105 of “n” optical devices 105-1 through 105-n is equal to “n ×dₓ.” It should be understood that in some implementations where the spacing between adjacent pairs of identical “n” optical devices 105-1 through 105-n is insignificant, the horizontal distance “dₓ” (i.e., the first pitch parameter) is substantially equal to a width of each optical device. However, in some other implementations, where an inter-device spacing is provided between adjacent optical devices amongst identical “n” optical devices 105-1 through 105-n, the horizontal distance “dₓ” is equal to the sum of a width of each optical device and the inter-device spacing between adjacent optical devices.

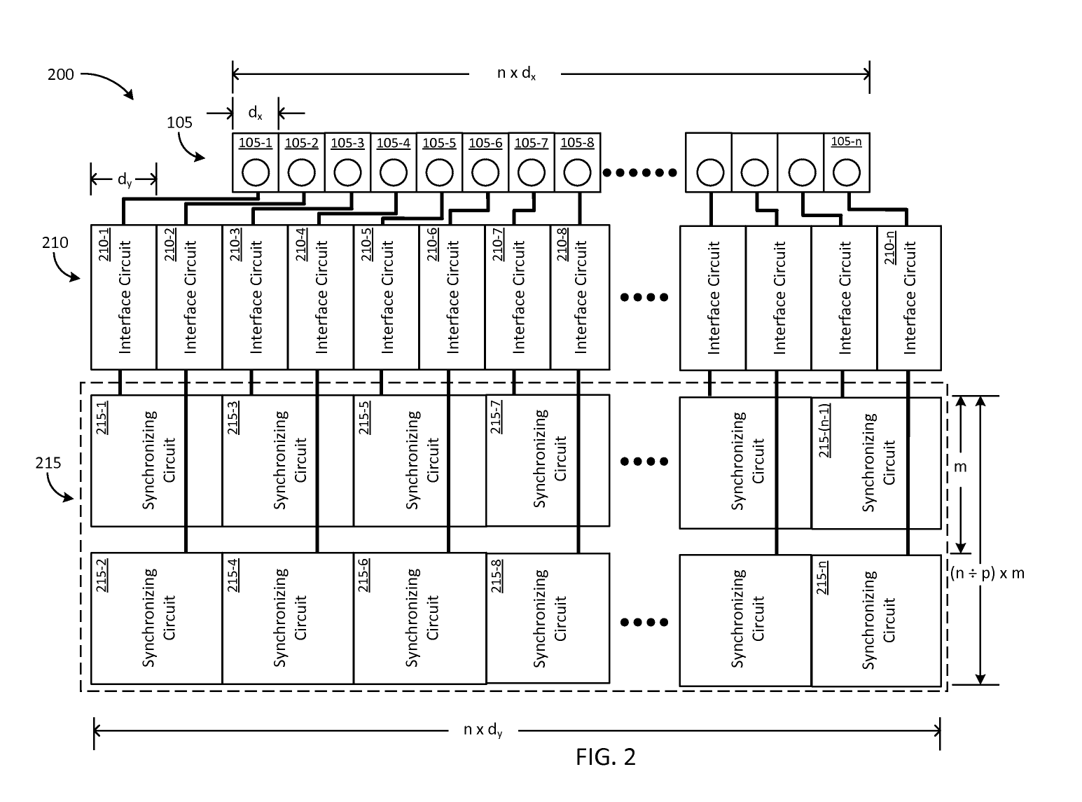

In one example implementation, each of the optical devices 105-1 through 105-n is a VCSEL, and the horizontal distance “dₓ” can lie anywhere in a 200 to 300 microns range. Determining a value for the horizontal distance “dₓ” can be carried out based on various criteria, including for example, a physical size of each of the optical devices 105-1 through 105-n and/or various physical characteristics of the substrate upon which the compact component arrangement 100 is fabricated. In some other embodiments, rather than being based on the physical size of each of the optical devices 105-1 through 105-n, the horizontal distance “dₓ” may be based on the area occupied by each of the interface circuits 110-1 through 110-n and/or a second pitch parameter that defines a spacing arrangement of the interface circuits 110-1 through 110-n. More specifically, the second pitch parameter defines a horizontal distance “d_{y}” between one side of the interface circuit 115-1 and a corresponding side of a neighboring interface circuit 115-2, wherein the two sides are oriented parallel to each other. This aspect will be described below in more detail using FIG. 2.

In the example embodiment shown in FIG. 1, the first pitch parameter is the same as the second pitch parameter. This relationship provides for each of the metal tracks that are similar to the metal track 106 to not only be short in length but also substantially identical to each other. As a result, the metal tracks interconnecting the “n” interface circuits 110-1 through 110-n to the “n” optical devices 105-1 through 105-n provide matched signal propagation characteristics for signals propagating through two or more of the metal tracks, especially when such signals are high frequency signals (radio frequency (RF) signals, for example).

Each of the synchronizing circuits 115-1 through 115-n typically include certain components that are relatively large in size. For example, one or more inductors can be larger in size than other components of the synchronizing circuits 115-1 through 115-n. Furthermore, the circuit density and number of components of each of the synchronizing circuits 115-1 through 115-n can be significantly greater than a single component, particularly when compared to each of the optical devices 105-1 through 105-n. Consequently, if the synchronizing circuits 115-1 through 115-n were to be arranged in a uniform linear array configuration that is similar to the first uniform linear array configuration 105 or the second uniform linear array configuration 110, a pitch parameter associated with the synchronizing circuits 115-1 through 115-n arranged side-by-side would be significantly larger than the first pitch parameter or the second pitch parameter.

Therefore, in accordance with the disclosure, the synchronizing circuits 115-1 through 115-n are arranged in a matrix array configuration 115 that incorporates (n ÷p) number of rows, where “n” is equal to either an integer multiple of 2 or an integer multiple of 3, and “p” is equal to an integer sub-multiple of “n.” As for size, the matrix array configuration 115 has an overall width equal to “n ×dₓ.” Accordingly, because the first pitch parameter “dₓ” defines an inter-device spacing of the “n” optical devices 105-1 through 105-n, a third pitch parameter that defines the inter-circuit spacing of the synchronizing circuits 115-1 through 115-n becomes an integer multiple of the first pitch parameter (“dₓ”).

To illustrate the matrix array configuration 115 in further detail using numerical examples, when “n” is equal to “32” (i.e., 2 ×16), “p” can be any integer sub-multiple of 32 (i.e., 2, 4, 8, or 16) and the corresponding number of rows will be 16, 8, 4, or 2 (i.e., even number of (n ÷p) rows). On the other hand, when “n” is equal to “243” (i.e., 3 ×81), “p” can be any integer sub-multiple of 243 (i.e., 3, 9, 27, or 81) and the corresponding number of rows will be 81, 27, 9, or 3 (i.e., odd number of (n ÷p) rows).

In this example embodiment shown in FIG. 1, the width of each of the synchronizing circuits 115-1 through 115-n is defined as a multiple of the first pitch parameter (“dₓ”), thus the overall linear horizontal width of the matrix array configuration 115 is equal to “n ×dₓ.” The overall linear height of the matrix array configuration 115 is equal to “(n ÷p) ×m” where “m” corresponds to a vertical pitch spacing between any two vertically neighboring synchronizing circuits among the synchronizing circuits 115-1 through 115-n. An example of this vertical pitch spacing “m” is shown in FIG. 1 with reference to the synchronizing circuits 115-n and 115-(n-1).

Attention is now drawn to FIG. 2, which shows a second exemplary embodiment of a compact component arrangement 200 that can be incorporated into an integrated circuit in accordance with the disclosure. The compact component arrangement 200 includes a first uniform linear array configuration 105 of “n” optical devices 105-1 through 105-n (n ≧2) that is similar to the first uniform linear array configuration 105 that is a part of the compact component arrangement 100 shown in FIG. 1.

However, the second uniform linear array configuration 210 of “n” interface circuits 210-1 through 210-n of the compact component arrangement 200 is different than the second uniform linear array configuration 110 of “n” interface circuits 110-1 through 110-n of the compact component arrangement 100 shown in FIG. 1. Specifically, the second pitch parameter that is defined by the horizontal distance “d_{y}” in the “n” interface circuits 210-1 through 210-n of the compact component arrangement 200 is different than the second pitch parameter of the compact component arrangement 100 shown in FIG. 1. Thus, unlike in the first example embodiment (illustrated by the compact component arrangement 100) where the second pitch parameter “d_{y}” is equal to the first pitch parameter “dₓ”, in the second example embodiment (illustrated by the compact component arrangement 200), the second pitch parameter “d_{y}” is greater than the first pitch parameter “dₓ”.

The matrix array configuration 215 of synchronizing circuits 215-1 through 215-n shown in FIG. 2 is similar to the matrix array configuration 115 of synchronizing circuits 115-1 through 115-n shown in FIG. 1 in terms of incorporating (n ÷p) number of rows, where “n” is equal to either an integer multiple of 2 or an integer multiple of 3, and “p” is equal to an integer sub-multiple of “n.” However, in contrast to the matrix array configuration 115 that has an overall width equal to “n ×dₓ,” the matrix array configuration 215 has an overall width equal to “n ×d_{y}” because the third pitch parameter is set equal to a multiple of the second pitch parameter rather than to a multiple of the first pitch parameter.

It should be understood that even though “n ×d_{y}” is larger than “n ×dₓ,” in certain example implementations, the overall layout area occupied by the matrix array configuration 215 upon a substrate can be kept the same as the overall layout area occupied by the matrix array configuration 115, by reducing the vertical pitch spacing “m.” In other words, the “(n ÷p) ×m” value of the matrix array configuration 215 can be selected to be smaller than the “(n ÷p) ×m” value of the matrix array configuration 115 in order to make the two matrix array configurations equal in area.

In certain other example implementations, “m” may be selected to be identical in the two matrix array configurations and the larger overall linear width of the matrix array configuration 215 can be used to accommodate a greater number of components in each of the “n” synchronizing circuits 215-1 through 215-n.

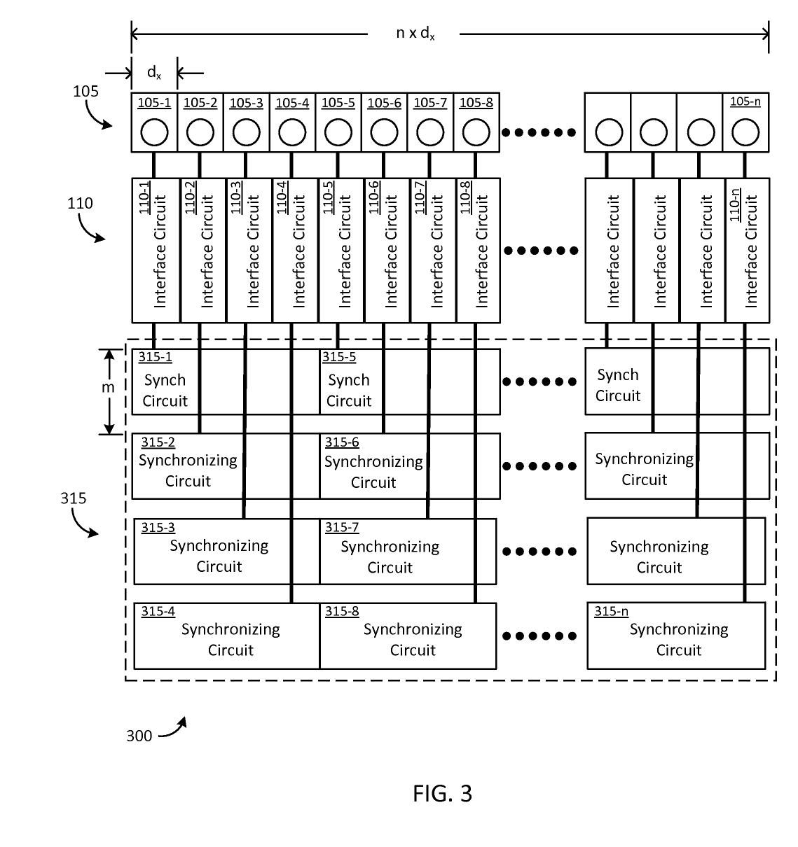

FIG. 3 shows a third exemplary embodiment of a compact component arrangement 300 that can be incorporated into an integrated circuit in accordance with the disclosure. The compact component arrangement 300 includes a first uniform linear array configuration 105 of “n” optical devices 105-1 through 105-n (n ≧2) and a second uniform linear array configuration 110 of “n” interface circuits 110-1 through 110-n that are similar to the first uniform linear array configuration 105 and the second uniform linear array configuration 110 of the compact component arrangement 100 shown in FIG. 1.

However, the matrix array configuration 315 of “n” synchronizing circuits 315-1 through 315-n of the matrix array configuration 315 is different than the matrix array configuration 115 of the compact component arrangement 100 shown in FIG. 1. Specifically, the third pitch parameter of the matrix array configuration 315 is different than the third pitch parameter of the matrix array configuration 115. As indicated above, the third pitch parameter is an integer multiple of the first pitch parameter (“d”). It can be understood from FIGS. 1 and 3 that the integer multiple applied to the third pitch parameter of the matrix array configuration 115 is two, whereas the integer multiple applied to the third pitch parameter of the matrix array configuration 315 is four.

As a result of the difference in the third pitch parameter, the number of rows in the matrix array configuration 315 is greater than the number of rows in the matrix array configuration 115. Notwithstanding the greater number of rows, the overall layout area occupied by the matrix array configuration 315 can be made the same as the overall layout area occupied by the matrix array configuration 115 by reducing the vertical pitch spacing “m.” In other words, the “(n ÷p) ×m” value of the matrix array configuration 315 can be made the same as the “(n ÷p) ×m” value of the matrix array configuration 115, thus making the overall layout area of the matrix array configuration 315 the same as the overall layout area of the matrix array configuration 115.

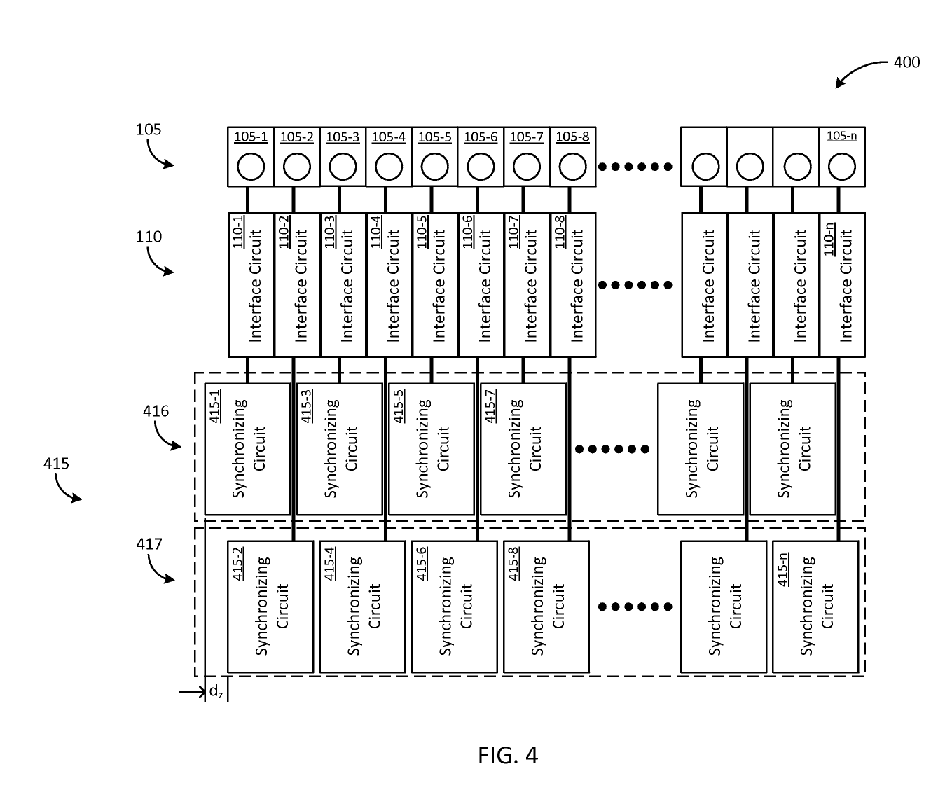

FIG. 4 shows a fourth exemplary embodiment of a compact component arrangement 400 that can be incorporated into an integrated circuit in accordance with the disclosure. The compact component arrangement 400 includes a first uniform linear array configuration 105 of “n” optical devices 105-1 through 105-n (n ≧2) and a second uniform linear array configuration 110 of “n” interface circuits 110-1 through 110-n that are similar to the first uniform linear array configuration 105 and the second uniform linear array configuration 110 of the compact component arrangement 100 shown in FIG. 1.

However, the matrix array configuration 415 of “n” synchronizing circuits 415-1 through 415-n of the matrix array configuration 415 incorporates two rows with a first row 416 being offset with respect to a second row 417. The offset, which is indicated by an offset distance “d_{z},” allows for placement of a corridor area between neighboring synchronizing circuits in the first row 416. The corridor areas can be used advantageously when implementing certain types of circuits using the compact component arrangement 400. To elaborate upon this aspect, attention is drawn to the metal tracks interconnecting the even numbered synchronizing circuits (i.e., synchronizing circuit 415-2, synchronizing circuit 415-4 etc.) with the even numbered interface circuits (i.e., interface circuit 110-2, interface circuit 110-4 etc.). Each of these metal tracks is routed through a corridor area that can be predefined in a substrate floor plan of the “n” synchronizing circuits 415-1 through 415-n of the matrix array configuration 415. The corridor area generally extends in a vertical direction between any two neighboring odd numbered synchronizing circuits (i.e., synchronizing circuit 415-1, synchronizing circuit 415-3, etc.). In contrast, corresponding metal tracks in the matrix array configuration 115 shown in FIG. 1 are routed through circuitry areas of the various odd numbered synchronizing circuits (i.e., synchronizing circuit 115-1, synchronizing circuit 115-3, etc.). The metal track in the circuitry areas shown in the matrix array configuration 115 may be predefined in each of the various odd numbered synchronizing circuits so as to create identically laid out synchronizing circuits. The identically laid out synchronizing circuits can provide certain advantages such as for example, predictable performance, repeatability, and better manufacturability.

However, the corridor areas provided in the matrix array configuration 415 not only provide advantages such as predictable performance, repeatability, and better manufacturability but also provide certain additional advantages such as reducing crosstalk between the signals of adjacent synchronizing circuits. Reducing crosstalk is very beneficial especially when the “n” synchronizing circuits 415-1 through 415-n are operated at high frequencies.

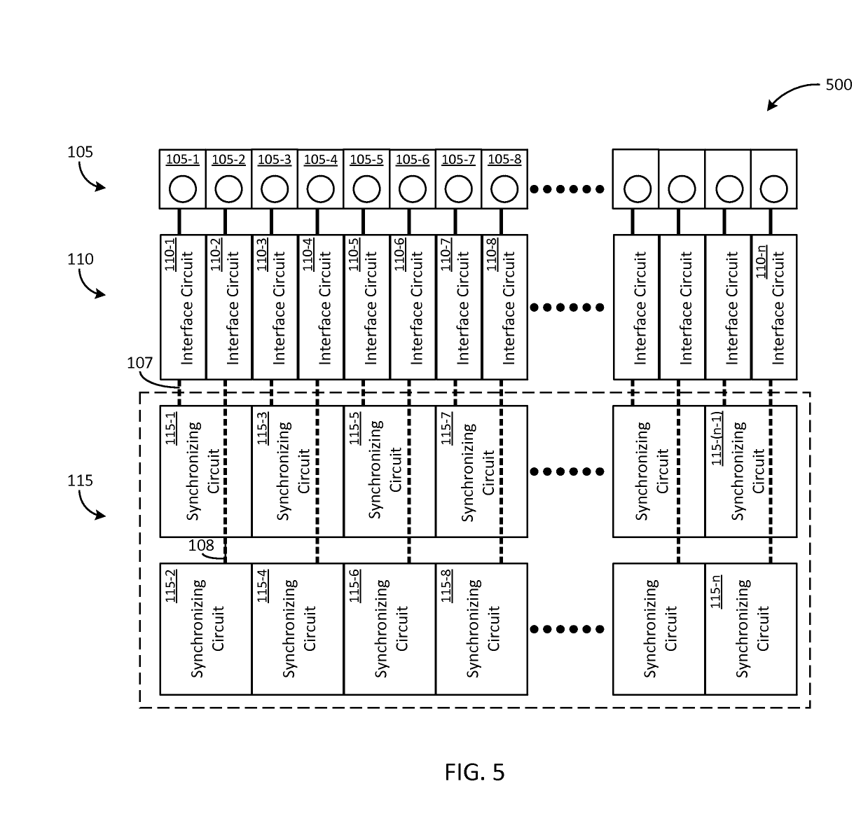

FIG. 5 shows a fifth exemplary embodiment of a compact component arrangement 500 that can be incorporated into an integrated circuit in accordance with the disclosure. The compact component arrangement 500 includes a first uniform linear array configuration 105 of “n” optical devices 105-1 through 105-n (n ≧2), a second uniform linear array configuration 110 of “n” interface circuits 110-1 through 110-n, and a matrix array configuration 115 that are similar to the first uniform linear array configuration 105, the second uniform linear array configuration 110, and the matrix array configuration 115 that of the compact component arrangement 100 shown in FIG. 1.

However, in this fifth exemplary embodiment, unlike in the first exemplary embodiment, some or all of the metal tracks that interconnect each of the “n” synchronizing circuits 115-1 through 115-n to the “n” interface circuits 110-1 through 110-n, such as metal tracks 107 and 108, are provided in one or more dedicated predesignated layers of a multilayer substrate upon which the compact component arrangement 500 is fabricated. For example, when the compact component arrangement 500 is configured for operating at high frequencies, some or all of the metal tracks can be fabricated on one dedicated layer in accordance with high frequency signal transmission practice, such as for example, in the form of striplines or microstrips. Furthermore, an adjacent coplanar layer that is located above or below the dedicated layer on which these metal tracks are fabricated may be configured as a ground plane layer so as to provide a desired characteristic impedance to one or more of the metal tracks.

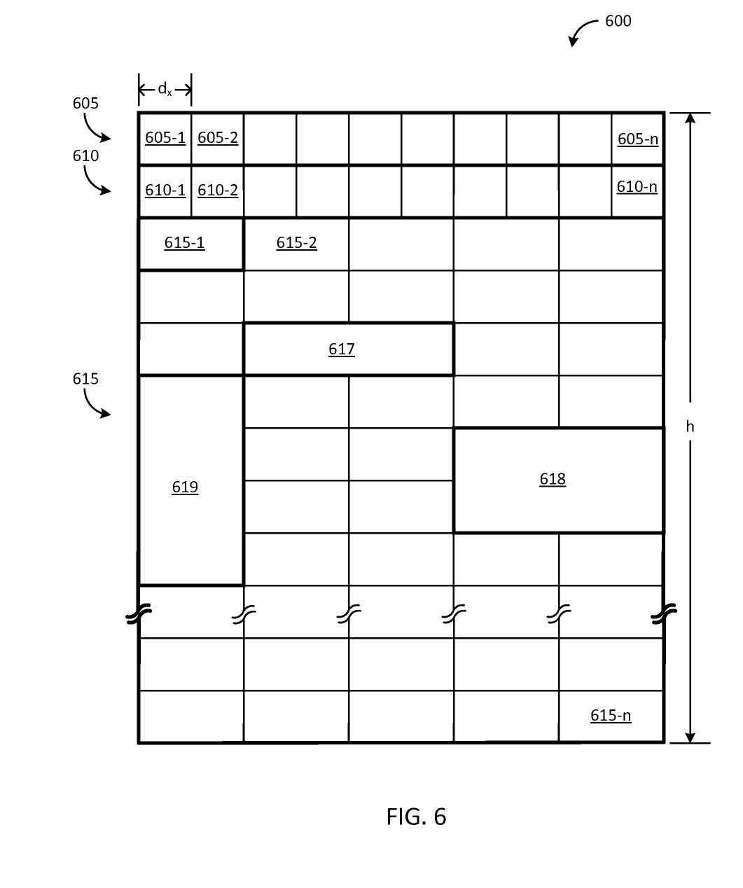

FIG. 6 shows an exemplary floor plan matrix array 600, which constitutes a substrate tiling pattern that can be used for fabricating various compact component arrangements in an integrated circuit in accordance with the disclosure. The floor plan matrix array 600 includes a first uniform linear array configuration 605 of “n” tiles 605-1 through 605-n (n ≧2) that define a layout pattern for “n” optical devices. In this exemplary embodiment, each of the “n” tiles 605-1 through 605-n is referred to as a fundamental tile.

The floor plan matrix array 600 also includes a second uniform linear array configuration 610 of “n” fundamental tiles 610-1 through 610-n that define a layout pattern for “n” interface circuits. The floor plan matrix array 600 further includes a matrix array configuration 615 of “n” tiles 615-1 through 615-n that define a layout pattern for “n” synchronizing circuits that can be selected to have various aspect ratios.

The dimension of a fundamental tile, such as the fundamental tile 605-1, is defined in terms of width, by a first pitch parameter “dₓ.” The height of each row of fundamental tiles can be varied in accordance with a desired overall height “h” of the floor plan matrix array 600. Drawing attention to the matrix array configuration 615 portion of the floor plan matrix array 600, various combinations of fundamental tiles can be used to define the size of a synchronizing circuit in various embodiments. For example, in a first embodiment, the size of a synchronizing circuit 615-1 can be defined as a combination of two horizontally adjacent fundamental tiles. In a second embodiment, the size of a synchronizing circuit 617 can be defined as a combination of four horizontally adjacent fundamental tiles. In a third embodiment, the size of a synchronizing circuit 618 can be defined as a combination of a first set of four horizontally adjacent fundamental tiles and a second set of four horizontally adjacent fundamental tiles. The first set of fundamental tiles is located parallel to the second set of fundamental tiles. In a fourth embodiment, the size of a synchronizing circuit 619 can be defined as a combination of four sets, each set formed of two horizontally adjacent fundamental tiles. The four sets of fundamental tiles are located parallel to each other. The matrix array configuration 615 portion of the floor plan matrix array 600 can be suitably populated with each of an appropriate number of these various synchronizing circuits 615-1, 617, 618, or 619 in accordance with the desired height (“h”) of the floor plan matrix array 600.

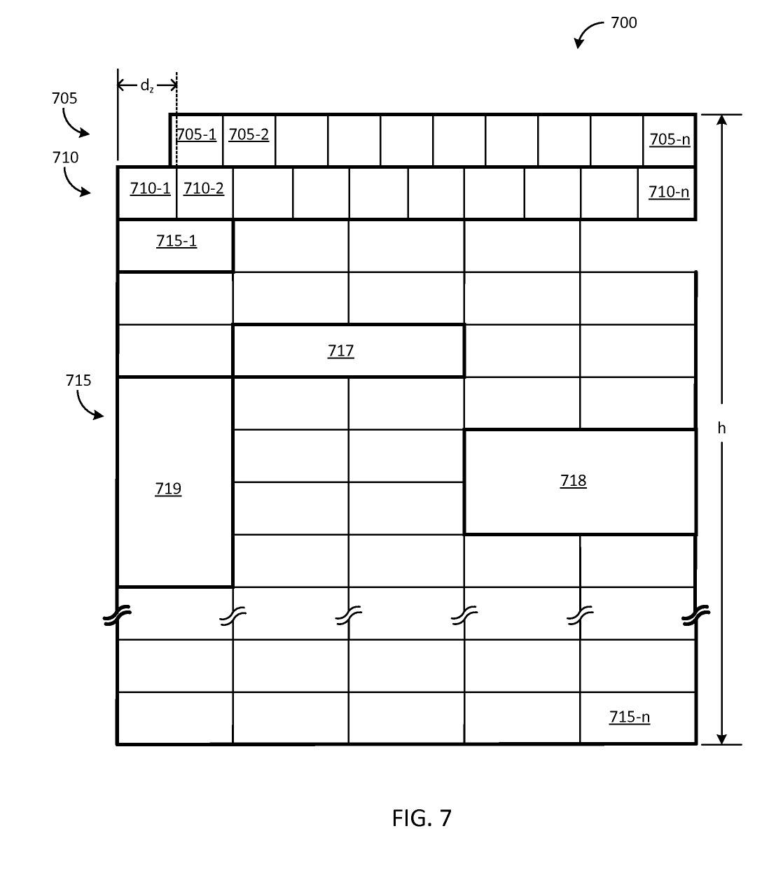

FIG. 7 shows an exemplary floor plan matrix array 700, which constitutes another substrate tiling pattern that can be used for fabricating various compact component arrangements in an integrated circuit in accordance with the disclosure. The floor plan matrix array 700 includes a first uniform linear array configuration 705 of “n” tiles 705-1 through 705-n (n ≧2) that define a layout pattern for “n” optical devices; a second uniform linear array configuration 710 of “n” tiles 710-1 through 710-n that define a layout pattern for “n” interface circuits; and a matrix array configuration 715 of “n” tiles 715-1 through 715-n that define a layout pattern for “n” synchronizing circuits that can be selected to have various aspect ratios.

Unlike in the floor plan matrix array 600 where a fundamental tile is defined with respect to the tiles of the first uniform linear array configuration 605, in the floor plan matrix array 700, a fundamental tile is defined with respect to the second uniform linear array configuration 710, such as for example, the fundamental tile 710-1. Specifically, a width of a fundamental tile of the floor plan matrix array 700 is defined by a second pitch parameter defined in the form of a horizontal distance “d_{z}” between any two adjacent interface circuits. The height of each row of fundamental tiles can be varied in accordance with a desired overall height “h” of the floor plan matrix array 700. The exemplary synchronizing circuits 715-1, 717, 718, and 719 are similar to the exemplary synchronizing circuits 615-1, 617, 618, and 619 of floor plan matrix array 700 except that the width of each of the exemplary synchronizing circuits 715-1, 717, 718, and 719 is a multiple of “d_{z}” rather than a multiple of “dₓ.”

In summary, it should be noted that the invention has been described with reference to a few illustrative embodiments for the purpose of demonstrating the principles and concepts of the invention. It will be understood by persons of skill in the art, in view of the description provided herein, that the invention is not limited to these illustrative embodiments. For example, in other embodiments, the first uniform linear array, the second uniform linear array, and the matrix array configuration can contain elements other than the optical devices, the interface circuits, and the synchronizing circuits referred to in the illustrative embodiments herein. Persons of skill in the art will understand that many such variations can be made to the illustrative embodiments without deviating from the scope of the invention.

What is claimed is:

1. An integrated circuit comprising:
a plurality of optical devices arranged in a first uniform linear array configuration, the first uniform linear array configuration having a first pitch parameter that defines a first horizontal distance between one side of a first optical device and a corresponding parallel side of a neighboring optical device;
a plurality of interface circuits coupled one-to-one to the plurality of optical devices, the plurality of interface circuits arranged in a second uniform linear array configuration that extends parallel to the first uniform linear array configuration, the second uniform linear array configuration having a second pitch parameter that defines a second horizontal distance between one side of a first interface circuit and a corresponding parallel side of a neighboring interface circuit; and
a plurality of synchronizing circuits coupled one-to-one to the plurality of interface circuits, the plurality of synchronizing circuits arranged in a matrix array configuration comprising at least two rows with a first row of the at least two rows extending parallel to the second linear array configuration, the matrix array configuration having a third pitch parameter that defines a third horizontal distance between one side of a first synchronizing circuit and a corresponding parallel side of a neighboring synchronizing circuit of a row, the third pitch parameter being equal to a multiple of the second pitch parameter.

2. The integrated circuit of claim 1, wherein the plurality of optical devices equals “n” optical devices, the plurality of interface circuits equals “n” interface circuits, the plurality of synchronizing circuits equals “n” synchronizing circuits, and the matrix configuration comprises (n÷p) number of rows, where “p” is an integer sub-multiple of “n.”

3. The integrated circuit of claim 2, wherein “n” is equal to one of an integer multiple of 2 or an integer multiple of 3.

4. The integrated circuit of claim 3, wherein each of the plurality of optical devices is identical to the remaining plurality of optical devices, and wherein the first pitch parameter is based on at least one of a dimension of each optical device or a substrate layout tiling pattern.

5. The integrated circuit of claim 4, wherein the second pitch parameter is equal to the first pitch parameter.

6. The integrated circuit of claim 3, wherein the plurality of interface circuits comprises at least one of a transmitter circuit, a receiver circuit, or a transceiver circuit.

7. The integrated circuit of claim 3, wherein each of the plurality of optical devices is a vertical cavity surface emitting laser (VCSEL).

8. An integrated circuit containing a matrix configuration of elements, the integrated circuit comprising:
“n” optical devices arranged in a first row of the matrix configuration;
“n” interface circuits coupled one-to-one to the “n” optical devices, the “n” interface circuits arranged in a second row of the matrix configuration; and
“n” synchronizing circuits coupled one-to-one to the “n” interface circuits, the “n” synchronizing circuits arranged in a remaining portion of the matrix configuration, the remaining portion of the matrix configuration containing (n ÷p) number of rows, where “p” is an integer sub-multiple of “n.”

9. The integrated circuit of claim 8, wherein “n” is equal to one of an integer multiple of 2 or an integer multiple of 3.

10. The integrated circuit of claim 8, wherein the first row of the matrix configuration has a first pitch parameter that defines a first horizontal distance between one side of a first optical device and a corresponding parallel side of a neighboring optical device, the second row of the matrix configuration has a second pitch parameter that defines a second horizontal distance between one side of a first interface circuit and a corresponding parallel side of a neighboring interface circuit, and each of the (n÷p) number of rows of the matrix configuration has a third pitch parameter that defines a third horizontal distance between one side of a first synchronizing circuit and a corresponding parallel side of a neighboring synchronizing circuit of a row, the third pitch parameter being equal to a multiple of the second pitch parameter.

11. The integrated circuit of claim 10, wherein the second pitch parameter is equal to the first pitch parameter.

12. The integrated circuit of claim 8, wherein the plurality of interface circuits comprises at least one of a transmitter circuit, a receiver circuit, or a transceiver circuit.

13. The integrated circuit of claim 8, wherein each of the plurality of optical devices is a vertical cavity surface emitting laser (VCSEL).

14. An integrated circuit comprising:
“n” interface circuits arranged in a first uniform linear array configuration, wherein the “n” interface circuits include at least one of a transmitter circuit, a receiver circuit, or a transceiver circuit, and wherein “n” is equal to one of an integer multiple of 2 or an integer multiple of 3; and
“n” synchronizing circuits coupled to a corresponding one of the “n” interface circuits, the “n” interface circuits arranged in a matrix configuration containing (n÷p) number of rows, wherein “p” is an integer sub-multiple of “n.”

15. The integrated circuit of claim 14, further comprising:
“n” optical devices arranged in a second uniform linear array configuration located parallel to the first uniform linear array configuration, each of the “n” optical devices coupled to a corresponding one of the “n” interface circuits.

16. The integrated circuit of claim 15, wherein the “n” optical devices, the “n” interface circuits and the “n” synchronizing circuits are mounted on a multi-layer substrate.

17. The integrated circuit of claim 16, wherein a plurality of metal tracks provide coupling of the “n” synchronizing circuits to the “n” interface circuits, the plurality of metal tracks located in a first layer that is exclusively dedicated for accommodating the plurality of metal tracks.

18. The integrated circuit of claim 17, wherein each of the plurality of metal tracks is at least one of a microstrip or a stripline, and wherein the multi-layer substrate includes a ground plane layer located coplanar to the first layer.

19. The integrated circuit of claim 16, wherein a plurality of metal tracks provide coupling of the “n” synchronizing circuits to the “n” interface circuits, and wherein a subset of the plurality of metal tracks is routed through a corridor area that is defined with respect to a substrate floor plan of the “n” synchronizing circuits.

20. The integrated circuit of claim 19, wherein the substrate floor plan is a substrate layout tiling pattern and wherein the corridor area is defined as a linear corridor that extends vertically between two adjacent tiles of the substrate layout tiling pattern.
